(19) United States
(12) Patent Application Publication
(10) Pub. No.: US 2009/0027856 A1
(43) Pub. Date: Jan. 29, 2009

(54) BLADE COOLING SYSTEM USING WET AND DRY HEAT SINKS

(76) Inventor: Scott McCoy, Halfway, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/828,738

(22) Filed: Jul. 26, 2007

(51) Int. Cl. H05K 7/20

(52) U.S. Cl. 361/699; 165/80.4

(57) ABSTRACT

An enclosure is disclosed. The enclosure comprises a chassis having a plurality of slots configured to hold a plurality of blades. At least one wet heat sink is positioned adjacent to each of the plurality of slots. An input piping system is coupled to the wet heat sinks and configured to supply cooling fluid to each of the wet heat sinks. An exhaust piping system is also coupled to the wet heat sinks and configured to remove the cooling fluid from the wet heat sinks. At least one blade is installed into one of the slots. The blade has at least one dry heat sink attached to the blade. The at least one dry heat sink is in thermal contact with the at least one wet heat sink positioned adjacent to the first slot.

### BACKGROUND

High density enclosures like blade and cellular systems are limited by their ability to dissipate heat into the air with fans and heat sinks. Liquid cooling can significantly improve cooling capacity and power density of such systems by removing heat more efficiently and in less space than an air cooled system. The multiple fluid connections or couplings required for maintenance adds complexity and increases the risk of fluid leakage. The risk of a leak effecting nearby equipment discourages the use of liquid cooling.

### BRIEF DESCRIPTION OF THE DRAWINGS

FIG. 1 is a block diagram of blade 102 inserted into chassis 104 of enclosure 100 in an example embodiment of the invention.

FIG. 2 is a block diagram of blade 202 being inserted into chassis 204 of enclosure 200 in an example embodiment of the invention.

### DETAILED DESCRIPTION

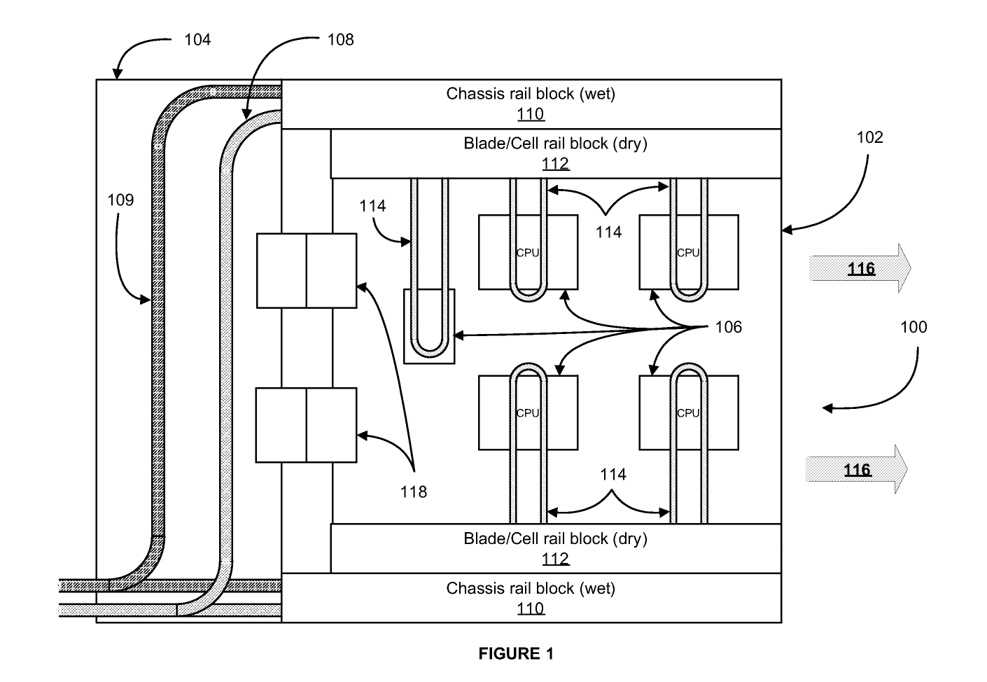

FIG. 1 is a block diagram of blade 102 inserted into chassis 104 of enclosure 100 in an example embodiment of the invention. Enclosure 100 may also be known as a blade enclosure. Blade 102 has a number of components 106, for example computer processing units (CPU), that require cooling. Blade 102 may be a server, a storage/memory board or some other type of peripheral blade. Blade 102 may also be known as a cell in some systems. Blade 102 has blade/cell rail blocks 112 attached to each side of blade 102. Blade/cell rail blocks 112 act as dry heat sinks for blade 102. Blade/cell rail blocks 112 are used to mount blade 102 into chassis 104 of enclosure 100. Blade/cell rail blocks 112 are configured to mate with chassis rail blocks 110 in chassis 104. In one example embodiment of the invention, blade/cell rail blocks 112 slide into grooves formed into chassis rail blocks 110. Connectors 118 electrically couple blade 102 to chassis 104. Chassis 104 may also be known as an enclosure in some blade systems.

Chassis rail blocks 110 are part of chassis 104. Chassis rail blocks 110 are configured to allow blade 102 to be inserted into enclosure 100. Enclosure 100 may contain a plurality of chassis rail blocks 110 configured to accept a plurality of blades 102. Chassis rail blocks 110 are liquid cooled. Chassis rail blocks 110 act as wet heat sinks for Blade/cell rail blocks 112. In one example embodiment of the invention, tubes or hollow passageways extend down the length of chassis rail blocks 110. Input conduit 108 is coupled to the tubes or passageways of chassis rail block 110 and feed cooling liquid into both chassis rail blocks 110. Exhaust conduit 109 is coupled to the tubes or passageways of chassis rail blocks 110 and returns the coolant back to a heat exchanger (not shown for clarity). Once the cooling fluid enters the chassis, the cooling fluid is wholly contained inside chassis 104 and is not coupled to blade/cell rail blocks 112.

The input and exhaust conduits (108 and 109) for each set of two chassis rail blocks 110 may be coupled together and connected to a common cooling fluid hookup. This allows a single fluid coupling to supply cooling fluid to all the blades in enclosure 100. Because the cooling fluid does not enter the blades, the cooling system may be tested for leaks before any blades are installed into enclosure 100. In one example embodiment of the invention, air may be forced past blade 102, as shown by arrows 116, as an additional source of cooling for blade 102.

In one example embodiment of the invention, two chassis rail blocks 110 make up a set of chassis rail blocks. Each set of chassis rail blocks act as the wet heat sinks for each of the plurality of blades mounted into an enclosure. In another example embodiment of the invention, the blades may only be liquid cooled from one side of the blades. The blades would only have one blade/cell rail block 112 located on one side of the blades. The single blade/cell rail block 112 would couple to a single chassis rail block. The empty side of the blade would couple to a normal chassis frame in the enclosure (i.e. a side without a heat sink).

During normal operation, heat from components 106 is transferred to blade/cell rail blocks 112. In one example embodiment of the invention, optional phase change thermal pipes 114 may be coupled to blade/cell rail blocks 112 and positioned over components 106. Phase change thermal pipes 114 may be used to help transfer heat from components 106 to blade/cell rail blocks 112. Blade/cell rail blocks 112 are in thermal contact with chassis rail blocks 110 and heat is transferred from the blade/cell rail blocks 112 to the chassis rail blocks 110. Cooling fluid removes heat from chassis rail blocks 110 as cooling fluid circulates through chassis rail blocks 110. Advantageously, cooling fluid stays inside chassis 104 and does not circulate into blade/cell rail block 112. Because there is no fluid transfer between chassis 104 and blade/cell rail block 112, blade 102 can be installed or removed from chassis 104 without danger of fluid leakage.

In one example embodiment of the invention, thermal grease or other substances may be used to increase the thermal coupling between chassis rail blocks 110 and blade/cell rail blocks 112.

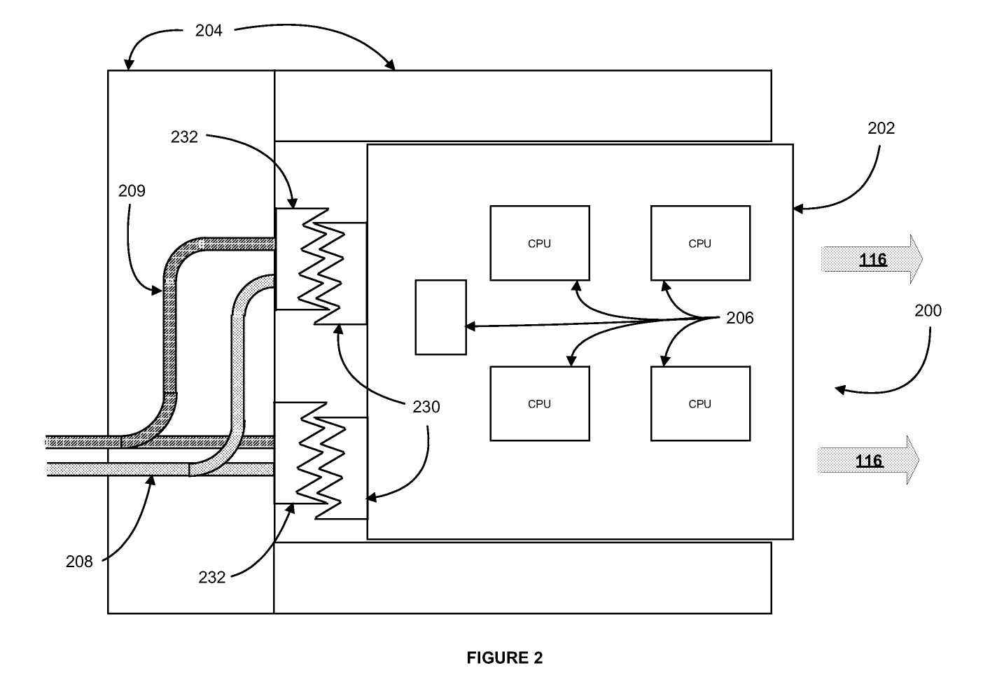

FIG. 2 is a block diagram of blade 202 being inserted into chassis 204 of enclosure 200 in an example embodiment of the invention. Blade 202 has a number of components 106, for example computer processing units (CPU), that require cooling. Blade 202 may be a server, a storage/memory blade or some other type of peripheral blade. Blade 202 has dry heat sinks 230 attached to one end of blade 202. The two sides of blade 202 are used to guide blade 202 into chassis 204 of enclosure 200. Dry heat sinks 230 are configured to mate with wet heat sinks 232 in chassis 204. Connectors (not shown for clarity) may electrically couple blade 202 to chassis 204. Chassis 204 may also be known as an enclosure in some blade systems.

In one example embodiment of the invention, tubes or hollow passageways extend inside wet heat sinks 232. Input conduit 208 is coupled to the tubes or passageways inside wet heat sinks 232 and feed cooling liquid into both wet heat sinks 232. Exhaust conduit 209 is coupled to the tubes or passageways of wet heat sinks 232 and returns the coolant back to a heat exchanger (not shown for clarity). The cooling fluid is wholly contained inside chassis 204 and is not coupled to conduits on blade 202. The mating sides of wet and dry heat sinks (232 and 230) may be serrated to increase the contact surface are between the wet and dry heat sinks (232 and 230).

The input and exhaust conduits (208 and 209) for each set of two wet heat sinks may be coupled together and connected to a common cooling fluid hookup. This allows a single fluid coupling to supply cooling fluid to all the blades in enclosure 200. Because the cooling fluid stays inside chassis 204, the cooling system may be tested for leaks before any blades are installed into enclosure 200. In one example embodiment of the invention, air may be forced past blade 202, as shown by arrows 116, as an additional source of cooling for blade 202.

During normal operation, heat from components 206 is transferred to dry heat sinks 230. In one example embodiment of the invention, optional phase change thermal pipes may be coupled to dry heat sinks 230 and positioned over components 206. Phase change thermal pipes may be used to help transfer heat from components 206 to dry heat sinks 230. Dry heat sinks 230 are in thermal contact with wet heat sinks 232 and heat is transferred from dry heat sinks 230 to the wet heat sinks 232. Cooling fluid removes heat from wet heat sinks 232 as cooling fluid circulates through wet heat sinks 232. Advantageously, cooling fluid stays inside chassis 204 and does not circulate into dry heat sinks 230. Because there is no fluid transfer between chassis 204 and dry heat sinks 230, blade 202 can be installed or removed from chassis 204 without danger of fluid leakage.

In one example embodiment of the invention, thermal grease or other substances may be used to increase the thermal coupling between dry heat sink 230 and wet heat sink 232.

What is claimed is:

1. A enclosure, comprising:
a chassis having a plurality of slots configured to hold a plurality of blades;
a plurality of wet heat sinks wherein at least one wet heat sink is positioned adjacent to each of the plurality of slots;
an input piping system coupled to the plurality of wet heat sinks and configured to supply cooling fluid to each of the plurality of wet heat sinks;
an exhaust piping system coupled to the plurality of wet heat sinks and configured to remove the cooling fluid from each of the plurality of wet heat sinks;
at least one blade installed into a first of the plurality of slots wherein the at least one blade has at least one dry heat sink attached to the blade and where the at least one dry heat sink is in thermal contact with the at least one wet heat sink positioned adjacent to the first slot.

2. The enclosure of claim 1, further comprising:
at least one phase change heat pipe coupled to the at least one dry heat sink and positioned over at least one component mounted onto the at least one blade installed into the first of the plurality of slots.

3. The enclosure of claim 1, wherein the thermal contact between the at least one dry heat sink and the at least one wet heat sink is along a serrated surface.

4. The enclosure of claim 1, wherein the input piping system has a single fluid connector configured to couple the input piping system to an external source for cooling fluid.

5. The enclosure of claim 1, wherein the plurality of wet heat sinks are positioned adjacent a front end of each of the plurality of slots.

6. The enclosure of claim 1, wherein the plurality of wet heat sinks are positioned along at least one side of each of the plurality of slots.

7. The enclosure of claim 1, wherein a thermal grease is used at the thermal contact between the at least one dry heat sink and the at least one wet heat sink.

8. The enclosure of claim 1, wherein each of the plurality of wet heat sinks form a chassis rail block and where a chassis rail block is positioned along each side of the plurality of slots and configured to hold one of the plurality of blades in the slot along essentially a full length of the blade.

9. The enclosure of claim 8, further comprising:
a first and a second dry heat sink formed as blade/cell rail blocks where the first blade/cell rail block is attached to a first side of the at least one blade and the second blade/cell rail block is attached to a second side of the at least one blade and where the first and second blade/cell rail block extend essentially along a full length of the at least one blade and are coupled to the chassis rail blocks.

10. The enclosure of claim 1, wherein the at least one blade is selected from the following group comprising: a server and a storage/memory board.

11. A method for cooling an enclosure, comprising:
transferring heat from a blade into a dry heat sink wherein the dry heat sink is mounted on the blade;
transferring heat from the dry heat sink into a wet heat sink wherein the wet heat sink is in thermal contact with the dry heat sink and is attached to a chassis of the enclosure;
transferring heat away from the wet heat sink by circulating cooling fluid through the wet heat sink.

12. The method for cooling an enclosure of claim 11, wherein at least one phase change heat pipe is coupled to the at least one dry heat sink and positioned over at least one component mounted onto the blade and configured to help transfer the heat from the component to the dry heat sink.

13. The method for cooling an enclosure of claim 11, wherein the thermal contact between the at least one dry heat sink and the at least one wet heat sink is along a serrated surface.

14. The method for cooling an enclosure of claim 11, wherein an input piping system is used to circulate cooling fluid through the wet heat sink and where the input piping system has a single fluid connector configured to couple the input piping system to an external source for cooling fluid.

15. The method for cooling an enclosure of claim 11, wherein the dry heat sink is mounted on a front end of the blade.

16. The method for cooling an enclosure of claim 11, wherein the dry heat sink is mounted on a side of the blade.

17. The method for cooling an enclosure of claim 11, wherein a thermal grease is used at the thermal contact between the at least one dry heat sink and the at least one wet heat sink.

18. The method for cooling an enclosure of claim 11, wherein the wet heat sink forms a chassis rail block and where the chassis rail block is positioned along a side of the blade and configured to hold the blade in the enclosure along essentially a full length of the blade.

19. The method for cooling an enclosure of claim 11, further comprising:
removing the blade from the enclosure without breaking a circuit holding the circulating cooling fluid.

20. An enclosure, comprising:
a means for mounting a plurality of blades into the enclosure;
a means for transferring heat from the plurality of blades into a plurality of dry heat sinks mounted onto the plurality of blades
a means for transferring heat from the plurality of dry heat sinks into a plurality of wet heat sinks;
a liquid cooling means for transferring the heat in the plurality of wet heat sinks to an external location.
